(19) United States
(12) Patent Application Publication
(10) Pub. No.: US 2013/0162298 A1
(43) Pub. Date: Jun. 27, 2013

(54) IDENTIFYING CIRCUIT

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., New Taipei (TW); HONG FU JIN PRECISION INDUSTRY (ShenZhen) CO., LTD ., Shenzhen City (CN)

(21) Appl. No.: 13/420,775

(22) Filed: Mar. 15, 2012

(30) Foreign Application Priority Data
Dec. 23, 2011 (CN) 201110437258.4

(51) Int. Cl. H03K 5/153

(52) U.S. Cl. 327/77

(57) ABSTRACT

An identifying circuit is connected between a Universal Serial Bus (USB) interface and a controller. The identifying circuit includes first and second resistors, and a diode. When a power adapter is connected to the USB interface, a negative data pin of the USB interface is floating, an identify pin of the controller receives a high level signal to determine that the power adapter is connected to the USB interface. When a computer is connected to the USB interface, the negative data pin of the USB interface outputs a low level signal, the identify pin of the controller receives a low level signal to determine that the USB interface is connected to the computer.

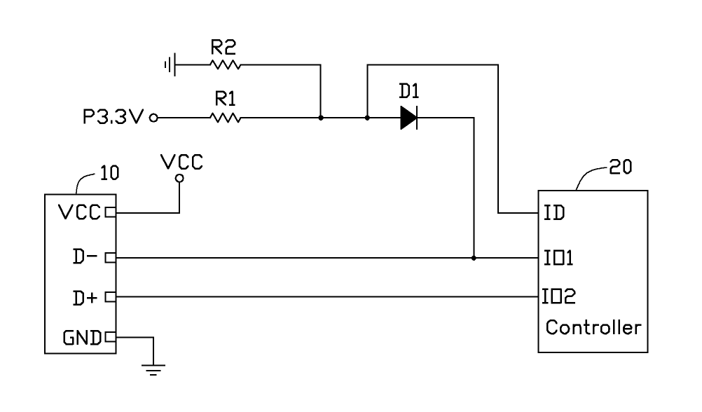

### BACKGROUND

1. Technical Field

The present disclosure relates to a USB interface.

2. Description of Related Art

Some electronic devices can be charged or recharged through their USB interface(s). The power to charge or recharge the electronic device may be supplied from a host, such as a computer, or directly from a USB mains power adapter. When the USB interface of the electronic device is connected to a computer through the USB cable, the electronic device is used as a USB device and can upload or download data from the computer. If the electronic device is not able to exchange data with the connected device such as when connected to a USB mains power adapter, the electronic device may ignore or shut down the connected USB interface. As a result, a controller of the electronic device must identify whether a computer or a power adapter has been connected to the USB interface. At present, a costly special identifying chip is used to identify the type of interface connected to the electronic device.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

The FIGURE is a circuit diagram of an exemplary embodiment of an identifying circuit for interface.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

Referring to the FIGURE, an identifying circuit is connected between a Universal Serial Bus (USB) interface 10 and a controller 20. An exemplary embodiment of the identifying circuit includes two resistors R1, R2, and a diode D1.

A power pin VCC of the USB interface 10 is connected to a power supply VCC. A positive data pin D+ and a negative data pin D− of the USB interface 10 are respectively connected to input/output pins 101 and 102 of the controller 20. As a result, when a USB device is connected to the USB interface 10, the power pin VCC supplies power for the USB device, and the positive data pin D+ and the negative data pin D− transmit data between the USB device and the controller 20.

The negative data pin D− of the USB interface 10 is further connected to a cathode of the diode D1. An anode of the diode D1 is connected to an identification pin ID of the controller 20. A 3.3 volt power supply P3.3V is grounded through the resistors R1 and R2 in series. A node between the resistors R1 and R2 is connected to the anode of the diode D1.

According to USB standards, a USB device includes a power pin, a ground pin, and two data pins. A power adapter includes a power pin and a ground pin.

When a power adapter is connected to the USB interface 10 through a USB cable, the negative data pin D− of the USB interface 10 is floating. At this time, a voltage received by the identify pin ID of the controller 20 is equal to a voltage which is obtained by the 3.3 volt power supply divided by the resistors R1 and R2. In this embodiment, a resistance of the resistor R1 is equal to 470K ohms, and a resistance of the resistor R2 is equal to 100K ohms. As a result, a voltage received by the identify pin ID of the controller 20 is equal to 2.7 volt, which can be regarded as a high level signal. The controller 20 determines that the power adapter is connected to the USB interface 10.

When a computer is connected to the USB interface 10 of the electronic device through the USB cable, the negative data pin D− outputs a low level signal. At this time, the diode D1 is turned on, and the identify pin ID of the controller 20 receives a low level signal. The controller 20 determines that the USB interface 10 is connected to the computer.

The foregoing description of the exemplary embodiments of the disclosure has been presented only for the purposes of illustration and description and is not intended to be exhaustive or to limit the disclosure to the precise forms disclosed. Many modifications and variations are possible in light of everything above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. An identifying circuit connected between a Universal Serial Bus (USB) interface and a controller, the identifying circuit comprising a first resistor, a second resistor, and a diode, a power supply is grounded through the first and second resistors in series, a node between the first and second resistors is connected to an anode of the diode, the anode of the diode is further connected to an identification pin of the controller, a cathode of the diode is connected to a negative data pin of the USB interface; wherein when a power adapter is connected to the USB interface, the negative data pin of the USB interface is floating, an identify pin of the controller receives a high level signal to determine that the power adapter is connected to the USB interface; when a computer is connected to the USB interface, the negative data pin of the USB interface outputs a low level signal, the identify pin of the controller receives a low level signal to determine that the USB interface is connected to the computer.
